(19) United States
(12) Patent Application Publication
(10) Pub. No.: US 2017/0234627 A1
(43) Pub. Date: Aug. 17, 2017

(54) COOLER AND FLOW PATH UNIT

(71) Applicants: Tomoyoshi Kobayashi, Aichi (JP); Koji Hachiya, Hyogo (JP); Eiji Shimoyama, Okayama (JP)

(72) Inventors: Tomoyoshi Kobayashi, Aichi (JP); Koji Hachiya, Hyogo (JP); Eiji Shimoyama, Okayama (JP)

(73) Assignees: OMRON AUTOMOTIVE ELECTRONICS CO., LTD., Aichi (JP); OMRON Corporation, Kyoto (JP)

(21) Appl. No.: 15/433,125

(22) Filed: Feb. 15, 2017

(30) Foreign Application Priority Data
Feb. 16, 2016 (JP) 2016-026761

(51) Int. Cl. F28F 1/40; F28F 1/04; H05K 7/20; F28F 1/02

(52) U.S. Cl. CPC F28F 1/40; F28F 1/022; F28F 1/04; H05K 7/20272

(57) ABSTRACT

A cooler includes: a bent flow path that is in thermal contact with a heating body, bends a flow direction of a refrigerant; and a dividing fin that divides the bent flow path into two or more divided paths in a curvature radial direction. A width of each of the divided paths in the curvature radial direction of the bent flow path is constant along the dividing fin. Inner curvature radii of the divided paths are substantially equal to each other, and outer curvature radii of the divided paths are substantially equal to each other. A thickness of the dividing fin in a center portion of the bent flow path in the curvature radial direction is thicker than a thickness of the dividing fin in an upstream portion and a downstream portion of the bent flow path in the curvature radial direction.

### CROSS-REFERENCES TO RELATED APPLICATIONS

This application is based upon and claims the benefit of priority from Japanese Patent Application No. 2016-026761, filed on Feb. 16, 2016, the entire contents of which are incorporated herein by reference.

### FIELD

One or more embodiments of the present invention relate to a cooler in which heat generated by a heating body is radiated by causing a refrigerant to flow through a flow path being in thermal contact with the heating body. In addition, one or more embodiments of the present invention relate to a flow path unit including a bent flow path for bending a flow direction of a fluid.

### BACKGROUND

In order to radiate heat generated by a heating body such as an electronic component, there is a cooler in which a refrigerant such as cooling water flows through a flow path being in thermal contact with the heating body. In such a cooler, in order to cause the refrigerant to smoothly flow through the flow path and to improve cooling efficiency, for example, in JP-A-2014-20115 and JP-A-2015-154699, a plurality of ribs or fins are provided within the flow path and the flow path is divided.

In JP-A-2014-20115, a straight flow path for causing the refrigerant to straightly flow and a bent flow path for bending the flow direction of the refrigerant are connected. The heating body is in thermal contact with the straight flow path. Therefore, in order to promote a turbulent flow of the refrigerant, a plurality of corrugated fins are respectively provided in the straight flow path at predetermined intervals in the flow direction of the refrigerant and in a width direction of the flow path, In addition, in order to smoothly guide the refrigerant, bent fins are provided in the bent flow path at predetermined intervals in the width direction of the flow path.

In JP-A-2015-154699, the heating body is in thermal contact with the bent flow path that is bent in a U shape. Therefore, in order to smoothly guide the refrigerant, a plurality of arcuate ribs (protrusion portions) are respectively provided in the bent flow path at predetermined intervals in the flow direction of the refrigerant and the width direction of the flow path. The ribs also functions as radiating fins.

In addition, in order to smoothly guide a fluid in other flow paths such as one for air conditioning, techniques for dividing the bent flow path in a curvature radial direction are disclosed in JP-A-7-269524 and JP-A-2009-248866.

In JP-A-7-269524, a plurality of arcuate guide vanes are provided at predetermined intervals in the curvature radial direction of the bent flow path. Therefore, in order to cause a flow speed of the fluid flowing through each of divided paths that are divided by the guide vanes to be uniform, a bent shape of each divided path is similar.

In JP-A-2009-248866, in order to reduce noise when air flows through the bent flow path, a passage dividing wall portion having a crescent shape in a cross section is provided in the bent flow path and thereby the bent flow path is divided into two in the curvature radial direction. Therefore, the cross-sectional areas of two divided paths that are divided by the passage dividing wall portion are substantially equal to each other. In addition, a sum of the cross-sectional areas perpendicular to the passage dividing wall portion of two divided paths and a cross-sectional area of the straight flow paths that are respectively connected to an upstream side and a downstream side of the bent flow path are equal to each other.

FIGS. 7 and 8 are views illustrating bent flow paths 73 and 83 of coolers 70 and 80 of the related art. Each of the bent flow paths 73 and 83 is disposed, for example, within a housing (not illustrated) of a device including a heating body. Each of the bent flow paths 73 and 83 is provided with a plurality of dividing fins 76 and 86 for dividing each of the bent flow paths 73 and 83 in curvature radial directions Ri1 to Ri8 and Ro1 to Ro8. A thickness of each of the dividing fins 76 and 86 in the curvature radial directions Ri1 to Ri8 and Ro1 to Ro8 is constant.

In the example of FIG. 7, each of widths W1 to W8 of each of divided paths 73a, 73b, 73c, 73d, 73e, 73f, 73g, and 73h divided by dividing fins is constant along the dividing fins 76. Therefore, a flow speed of the refrigerant flowing through each of the divided paths 73a to 73h does not decrease and also cooling performance by the refrigerant does not decrease.

While, in a case of FIG. 7, as going to an outside of the bent flow path 73, inner curvature radii Ri1, Ri2, Ri3, Ri4, Ri5, Ri6, Ri7, and Ri8, and outer curvature radii Ro1, Ro2, Ro3, Ro4, Ro5, Ro6, Ro7, and Ro8 of each of the divided paths 73a to 73h increase (Ri1<Ri2<Ri3<Ri4<Ri5<Ri6<Ri7<Ri8, and Ro1<Ro2<Ro3<Ro4<Ro5<Ro6<Ro7<Ro8). Therefore, since an outer curvature radius Ro9 of the bent flow path 73 increases (Ro8<Ro9) and the refrigerant does not flow to a lower right region from the bent flow path 73 in FIG. 7, an effective cooling region Zb that is capable of being cooled by the refrigerant flowing through the bent flow path 73 is narrowed. Thus, a thermal contact area between the bent flow path 73 and the heating body mounted on the housing is reduced. Therefore, there is a concern that heat generated by the heating body cannot be effectively cooled by the refrigerant. In addition, the bent flow path 73 cannot be disposed in a narrow portion such as a corner portion of the housing and there is a concern that heat generated by the heating body mounted on the narrow portion cannot be cooled by the refrigerant.

In the example of FIG. 8, inner curvature radii Ri1′, Ri2′, Ri3′, Ri4′, Ri5′, Ri6′, Ri7′, and Ri8′ of each of the divided paths 83a, 83b, 83c, 83d, 83e, 83f, 83g, and 83h, divided by the dividing fins 86 are substantially equal to each other (Ri1′≅Ri2′≅Ri3′≅Ri4′≅Ri5′≅Ri6′≅Ri7′≅Ri8′). In addition, outer curvature radii Ro1′, Ro2′, Ro3′, Ro4′, Ro5′, Ro6′, Ro7′, and Ro8′ of each of the divided paths 83a to 83h, are also substantially equal to each other (Ro1′≅Ro2′≅Ro3′≅Ro4′≅Ro5′≅Ro6′≅Ro7≅Ro8′). Therefore, an outer curvature radius Ro9′ of the bent flow path 83 is smaller than the outer curvature radius Ro9 of the bent flow path 73 of FIG. 7 (Ro9>Ro9′) and an effective cooling region Zc that is capable of being cooled by the refrigerant flowing through the bent flow path 83 is widened (Zb<Zc).

While, in a case of FIG. 8, widths W1′ to W8′ of each of the divided paths 83a to 83h are changed along the dividing fins 86. Therefore, the flow speed of the refrigerant decreases at the widened portions of the widths W1′ to W8′ of each of the divided paths 83a to 83h. Therefore, the cooling performance by the refrigerant is also reduced.

### SUMMARY

An object of one or more embodiments of the inventions is to provide a cooler capable of improving cooling performance by widening a cooling region by reducing an outer curvature radius of a bent flow path without decreasing a flow speed of a refrigerant in the bent flow path, Another object of one or more embodiments of the inventions is to provide a flow path unit in which an outer curvature radius of a bent flow path is reduced without decreasing a flow speed of a fluid in the bent flow path.

A cooler according to one or more embodiments of the inventions includes a bent flow path that is in thermal contact with a heating body, bends a flow direction of a refrigerant flowing in from an upstream, and causes the refrigerant to flow out to a downstream; and a dividing fin that divides the bent flow path into two or more divided paths in a curvature radial direction. The refrigerant flows through each of the divideds path of the bent flow path, and heat generated by the heating body is radiated. Therefore, a width of each of the divided paths in the curvature radial direction of the bent flow paths is constant along the dividing fin. Inner curvature radii of the divided paths are substantially equal to each other, and outer curvature radii of the divided paths are substantially equal to each other. In addition, a thickness of the dividing fin in a center portion of the bent flow path in the curvature radial direction is thicker than a thickness of the dividing fin in an upstream portion and a downstream portion of the bent flow path in the curvature radial direction.

According to the cooler, in the bent flow path, the width of each of the divided paths divided by the dividing fin in the curvature radial direction is constant along the dividing fin. Therefore, it is possible to suppress decrease in the flow speed of the refrigerant flowing through each of the divided paths. Therefore, the refrigerant smoothly flows through each of the divided paths of the bent flow path, heat generated by the heating body being in thermal contact with the bent flow path can be efficiently radiated by the refrigerant, and cooling performance is improved.

In addition, the inner curvature radii of the divided paths are substantially equal to each other, and the outer curvature radii are also substantially equal to each other. The thickness of the dividing fin in the center portion in the curvature radial direction is thicker than that in the upstream portion or the downstream portion in the curvature radial direction. Therefore, the outer curvature radius of the bent flow path can be made as small as the outer curvature radius of the innermost divided path. Therefore, an entire width of the bent flow path is expanded and an effective cooling region capable of being cooled by the refrigerant flowing through the bent flow path can be widened. As a result, a thermal contact area between the bent flow path and the heating body is increased, heat generated by the heating body can be efficiently radiated by the refrigerant, and the cooling performance is improved. In addition, the bent flow path is disposed in a narrow space and heat generated by the heating body mounted on the narrow space can be radiated by the refrigerant.

In one or more embodiments of the inventions, in the cooler, a cross-sectional area of each of the divided paths perpendicular to the flow direction of the refrigerant may be constant along the dividing fin.

In addition, in one or more embodiments of the inventions, in the cooler, a cross-sectional shape of the dividing fin parallel to the curvature radial direction of the bent flow path and the flow direction of the refrigerant may be a crescent shape in which an inside of the bent flow path wanes.

In addition, in one or more embodiments of the inventions, in the cooler, widths of the divided paths perpendicular to the dividing fin may be substantially equal to each other, or the cross-sectional areas of the divided paths perpendicular to the flow direction of the refrigerant may be substantially equal to each other.

In addition, in one or more embodiments of the inventions, the cooler may further include: an upstream-side straight flow path that is connected to an upstream side of the bent flow path and causes the refrigerant to straightly flow; and a downstream-side straight flow path that is connected to a downstream side of the bent flow path and causes the refrigerant to straightly flow. The dividing fin may be provided in parallel to the flow direction of the refrigerant and over the upstream-side straight flow path, the bent flow path, and the downstream-side straight flow path.

In addition, in one or more embodiments of the inventions, in the cooler, a cross-sectional shape of the bent flow path perpendicular to the flow direction of the refrigerant may be rectangular. The dividing fin may be provided to have a columnar shape in the bent flow path and may transmit heat generated by the heating body to the refrigerant.

In addition, a flow path unit according to one or more embodiments of the inventions includes a bent flow path that bends a flow direction of a fluid flowing in from an upstream and causes the fluid to flow out to a downstream; and a dividing fin that divides the bent flow path into two or more divided paths in a curvature radial direction. The fluid flows through each of the divided paths of the bent flow path. A width of each of the divided paths in the curvature radial direction of the bent flow path is constant along the dividing fin. Inner curvature radii of the divided paths are substantially equal to each other, and outer curvature radii of the divided path are substantially equal to each other. In addition, a thickness of the dividing fin in a center portion of the bent flow path in the curvature radial direction is thicker than a thickness of the dividing fin in an upstream portion and a downstream portion of the bent flow path in the curvature radial direction.

According to the flow path unit, in the bent flow path, the width of each of the divided paths divided by the dividing fin in the curvature radial direction is constant along the dividing fin. Therefore, it is possible to suppress a decrease in the flow speed of the fluid flowing through each divided path. In addition, the inner curvature radii of the divided paths are substantially equal to each other, and the outer curvature radii are also substantially equal to each other. The thickness of the dividing fin in the center portion in the curvature radial direction is thicker than that in the upstream portion or the downstream portion in the curvature radial direction. Therefore, the outer curvature radius of the bent flow path can be made as small as the outer curvature radius of the innermost divided path.

According to the cooler of one or more embodiments of the inventions, cooling performance can be improved by widening a cooling region by reducing the outer curvature radius of the bent flow path without decreasing the flow speed of the refrigerant in the bent flow path. According to the flow path unit of one or more embodiments of the inventions, the outer curvature radius of the bent flow path can be reduced without decreasing the flow speed of the fluid in the bent flow path.

### BRIEF DESCRIPTION OF THE DRAWINGS

FIGS. 1A to 1C are views illustrating a cooler according to an embodiment of the invention.

FIG. 2 is a view illustrating an example of use of the cooler of FIGS. 1A to 1C.

FIG. 3 is a view illustrating an example of use of the cooler of FIGS. 1A to 1C.

FIG. 4 is an enlarged view of a bent flow path of the cooler of FIGS. 1A to 1C.

FIGS. 5A and 5B are cross-sectional views that are respectively taken along a VA-VA cross-section and a VB-VB cross-section of FIG. 4.

FIGS. 6A and 6B are diagrams illustrating an example of a simulation of the cooler of FIGS. 1A to 1C.

FIG. 7 is a view illustrating a bent flow path of a cooler of the related art.

FIG. 8 is a view illustrating a bent flow path of a cooler of the related art.

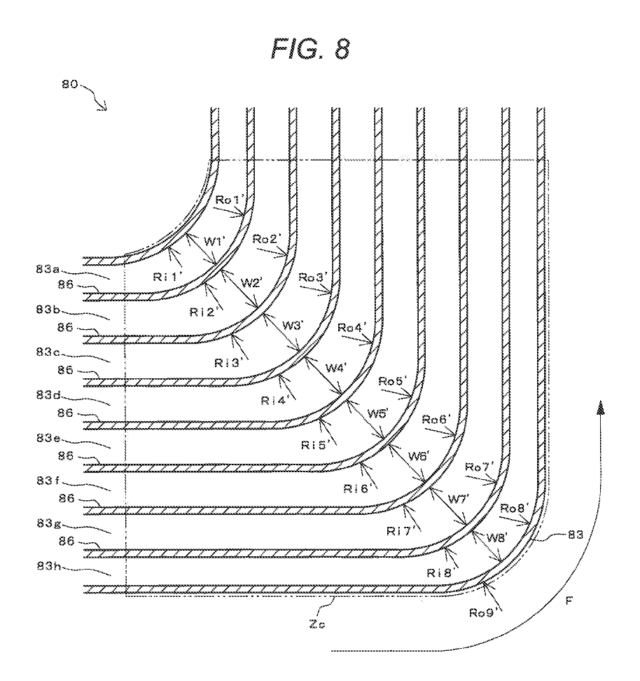

### DETAILED DESCRIPTION

In embodiments of the invention, numerous specific details are set forth in order to provide a thorough understanding of the invention. However, it will be apparent to one of ordinary skill in the art that the invention may be practiced without these specific details. In other instances, well-known features have not been described in detail to avoid obscuring the invention.
Hereinafter, embodiments of the invention will be described with reference to the drawings. The same reference numerals are given to the same portions or corresponding portions in each drawing.

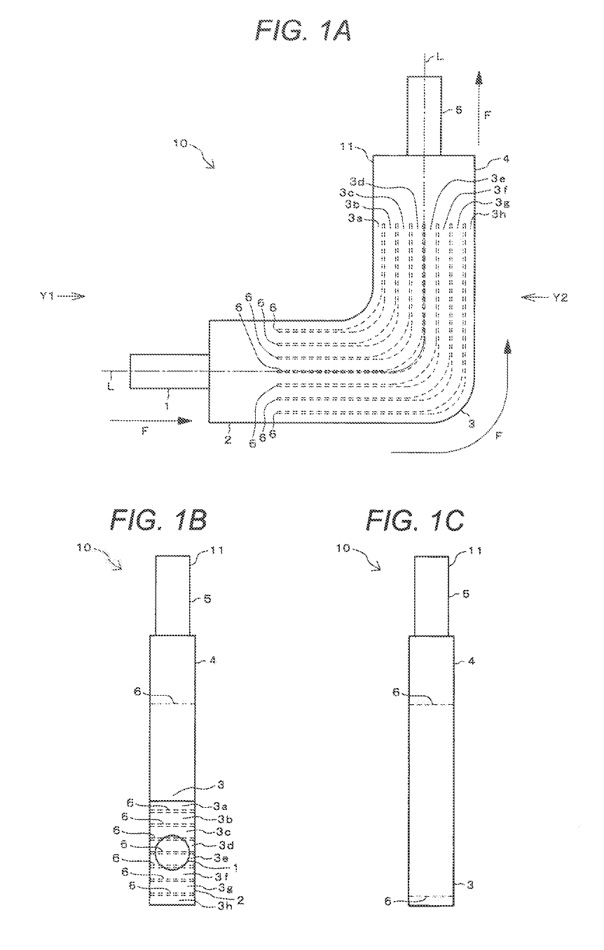

FIGS. 1A to 1C are views illustrating a cooler 10 according to an embodiment of the invention. In FIGS. 1A to 1C, FIG. 1A illustrates the cooler 10 viewed from above, FIG. 1B illustrates a view of the cooler 10 viewed from arrow Y1 of FIG. 1A, and FIG. 1C illustrates a view of the cooler 10 viewed from arrow Y2 of FIG. 1A.

The cooler 10 includes a pipe 11 that is formed of, for example, a metal having high thermal conductivity such as aluminum. The pipe 11 is provided with flow paths through which a refrigerant that is a fluid flows. As the refrigerant, for example, cooling water is used. The cooler 10 is an example of a “flow path unit” of one or more embodiments of the invention.

The pipe 11 includes narrow flow paths 1 and 5 having narrow cross-sectional areas perpendicular to a flow direction F of the refrigerant, and wide flow paths 2, 3, and 4 having wide cross-sectional areas perpendicular to the flow direction F of the refrigerant.

Among the narrow flow paths 1 and 5, one narrow flow path 1 configures a flow inlet of the refrigerant and the other narrow flow path 5 configures a flow outlet of the refrigerant. A cross-sectional shape of the narrow flow paths 1 and 5 perpendicular to the flow direction F of the refrigerant is circular (FIG. 1B).

As illustrated in FIG. 1A, the wide flow paths 2, 3, and 4 are provided between the narrow flow path 1 and the narrow flow path 5. Specifically, an upstream end of the wide flow path 2 is connected to a downstream end of the narrow flow path 1. In addition, an upstream end of the wide flow path 3 is connected to a downstream end of the wide flow path 2, and an upstream end of the wide flow path 4 is connected to a downstream end of the wide flow path 3. Furthermore, an upstream end of the narrow flow path 5 is connected to a downstream end of the wide flow path 4. Center lines L of the adjacent flow paths 1 to 5 coincide.

Among the wide flow paths 2, 3, and 4, the flow path 3 is a bent flow path that bends the flow direction F of the refrigerant to substantially 90°. The flow paths 2 and 4 are straight flow paths through which the refrigerant straightly flows. That is, the upstream-side straight flow path 2 and the downstream-side straight flow path 4 are connected to the upstream side and the downstream side of the bent flow path 3.

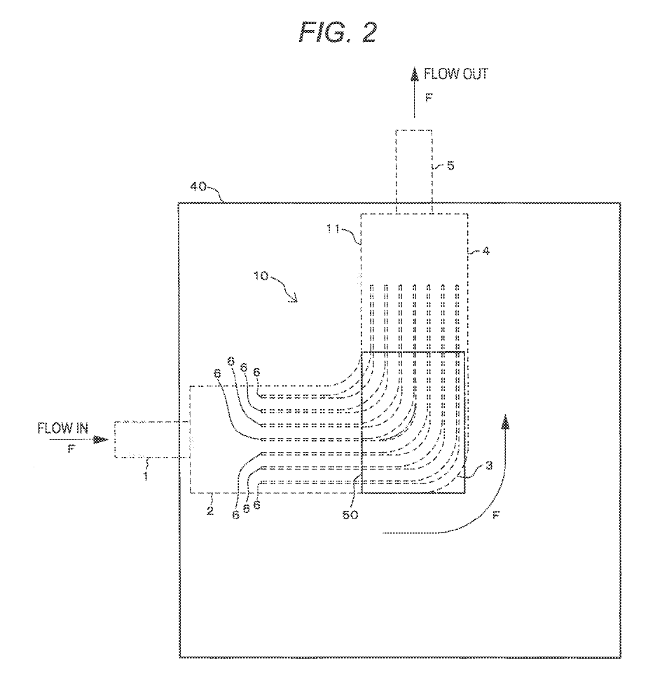

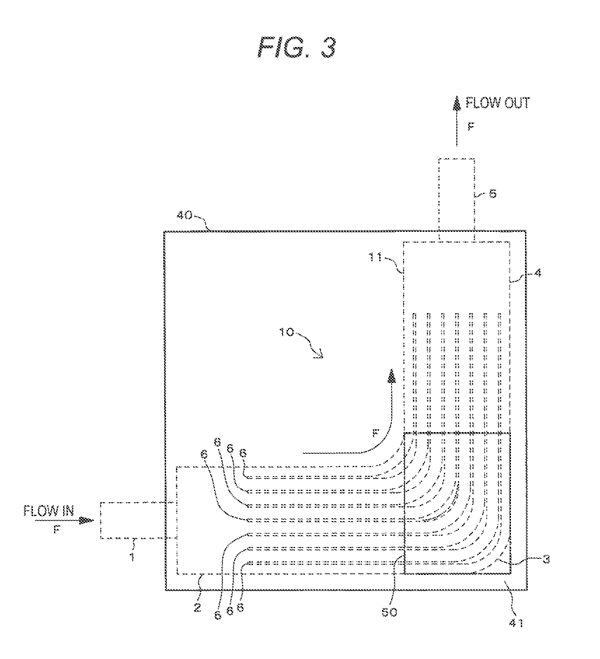

FIGS. 2 and 3 are views illustrating examples of use of the cooler 10. As illustrated in FIGS. 2 and 3, the cooler 10 is disposed within a housing 40 of an electronic device including a heating body 50. The housing 40 is formed in a box shape.

In the example of FIG. 2, the cooler 10 is disposed within the housing 40 so that the flow paths 2 to 4 are disposed in a center portion of the housing 40. In the example of FIG. 3, the cooler 10 is disposed within the housing 40 so that the flow paths 2 to 4 are disposed along a corner portion 41 of the housing 40. In order to cause the refrigerant to flow in and out with respect to the cooler 10, an upstream portion of the narrow flow path 1 and a downstream portion of the narrow flow path 5 protrude from the housing 40.

The heating body 50 is mounted on a position facing the bent flow path 3 on the housing 40. Therefore, the heating body 50 is in thermal contact with an outside portion of the pipe 11 configuring the bent flow path 3. The heating body 50 is configured of an electronic component that generates heat, for example, due to flow of a current.

The refrigerant flows from a supply source (not illustrated) into the narrow flow path 1 of the cooler 10 and the refrigerant flows from the narrow flow path 5 to a supply destination through the flow paths 2 to 4. As described above, the refrigerant flows through the flow paths 1 to 5 and thereby heat generated by the heating body 50 is radiated and the heating body 50 is cooled.

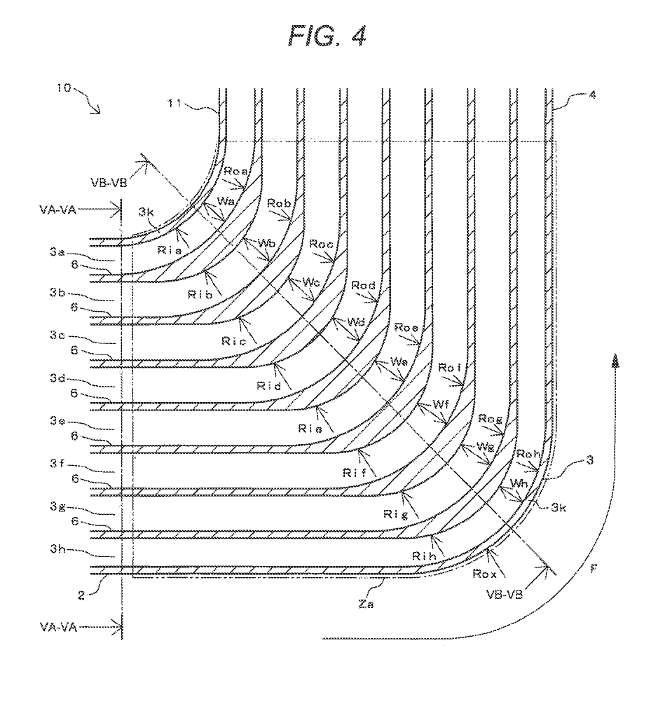

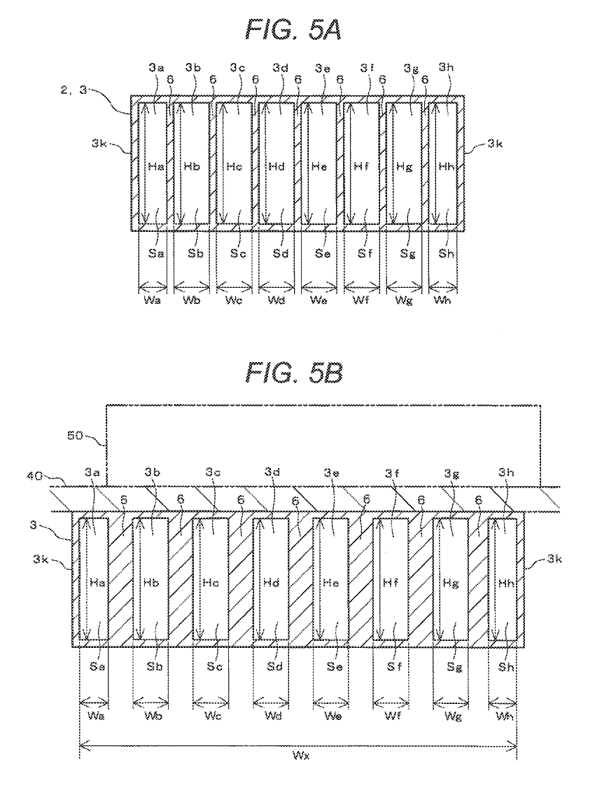

FIG. 4 is an enlarged view of the bent flow path 3 of the cooler 10. Specifically, FIG. 4 illustrates a state of an inside of the bent flow path 3 viewed from above. FIGS. 5A and 5B are cross-sectional views that are respectively taken along a VA-VA cross-section and a VB-VB cross-section of FIG. 4. The VA-VA cross-section and the VB-VB cross-section are perpendicular to the flow direction F of the refrigerant.

As illustrated in FIG. 4, dividing fins 6, which divides the bent flow path 3 into two or more in curvature radial directions Ria to Rih and Roa to Roh, are provided in the bent flow path 3. Specifically, a plurality (seven) of dividing fins 6 are provided at predetermined intervals in the curvature radial directions Ria to Rib and Roa to Roh.

As illustrated in FIGS. 5A and 5B, a cross-sectional shape of the bent flow path 3 perpendicular to the flow direction F of the refrigerant is rectangular. Each dividing fin 6 is provided in a columnar shape in the bent flow path 3 so as to connect to a top surface and a bottom surface of the bent flow path 3.

As illustrated in FIGS. 1A to 1C, each dividing fin 6 is provided parallel to the flow direction F of the refrigerant over the downstream portion of the upstream-side straight flow path 2, the bent flow path 3, and the upstream portion of the downstream-side straight flow path 4. Therefore, each of divided paths 3a, 3b, 3c, 3d, 3e, 3f, 3g, and 3h that is divided by the dividing fin 6 is formed over the downstream portion of the upstream-side straight flow path 2, the bent flow path 3, and the upstream portion of the downstream-side straight flow path 4.

Also in the straight flow paths 2 and 4, each dividing fin 6 is provided in a columnar shape so as to connect to the top surfaces and the bottom surfaces of the flow paths 2 and 4 (FIG. 1B). Similar to the bent flow path 3, a cross-sectional shape of the straight flow paths 2 and 4 perpendicular to the flow direction F of the refrigerant is rectangular (FIG. 1B). A cross-sectional shape of each of the divided paths 3a to 3h perpendicular to the flow direction F of the refrigerant is also rectangular (FIGS. 5A and 5B).

The refrigerant flows through each of the divided paths 3a to 3h and thereby heat generated by the heating body 50 being in thermal contact with the bent flow path 3 is radiated. In this case, each dividing fin 6 also functions as a radiating fin. That is, each dividing fin 6 is made of metal such as aluminum, heat generated by the heating body 50 is transmitted to the refrigerant flowing through each of the divided paths 3a to 3h, and the heat is radiated.

As illustrated in FIG. 4, in the bent flow path 3, a cross-sectional shape of each dividing fin 6 parallel to the curvature radial directions Ria to Rih and Roa to Roh and the flow direction F of the refrigerant is a crescent shape in which an inside of the bent flow path 3 wanes. That is, a thickness of the dividing fins 6 parallel to the curvature radial directions Ria to Rih and Ron to Roh is thickened as going to the center portion from the upstream portion and the downstream portion of the bent flow path 3. The thickness of the dividing fin 6 in the upstream portion of the bent flow path 3 from the downstream portion of the upstream-side straight flow path 2 and in the upstream portion of the downstream-side straight flow path 4 from the downstream portion of the bent flow path 3 is thinner than that in the center portion of the bent flow path 3, and is constant.

As described above, the dividing fins 6 are formed and thereby widths Wa to Wh of each of the divided paths 3a to 3h in the curvature radial direction of the bent flow path 3 is constant along the dividing fins 6. In addition, the inner curvature radii Ria to Rih of each of the divided paths 3a to 3h are substantially equal to each other (Ria≅Rib≅Ric≅Rid≅Rie≅Rif≅Rig≅Rih). In addition, the outer curvature radii Roa to Roh of each of the divided paths 3a to 3h are substantially equal to each other (Roa≅Rob≅Roc≅Rod≅Roe≅Rof≅Rog≅Roh).

Specifically, in the example of FIG. 4, the inner curvature radii Rib to Rig of the divided paths 3b to 3g other than the divided path 3a that is in the innermost side and the divided path 3h that is in the outermost side of the bent flow path 3 are equal to each other (Rib=Ric=Rid=Rie=Rif=Rig). The inner curvature radius Ria of the divided path 3a, the inner curvature radius Rib of the divided path 3h, and the inner curvature radii

Rib to Rig of the divided paths 3b to 3g are not equal to each other, but are substantially equal to each other (Ria≅Rib≅Rib≅to Rig). In addition, the outer curvature radius Roa to Rog of the divided paths 3a to 3g other than the divided path 3h that is in the outermost side of the bent flow path 3 are equal to each other (Roa=Rob=Roc=Rod=Roe=Rof=Rog). The outer curvature radius Roh of the divided path 3h and the outer curvature radii Roa to Rog of the divided paths 3a to 3g are not equal to each other, but are substantially equal to each other (Roh≅Roa to Rog).

In each of the divided paths 3a to 3h, the inner curvature radii Ria to Rih are smaller than the outer curvature radii Roa to Roh (Ria<Ron, Rib<Rob, Ric<Roc, Rid<Rod, Rie<Roe, Rif<Rof, Rig<Rog, and Rih<Roh). Among adjacent two divided paths, the inner curvature radius of the divided path on the outside is smaller than the outer curvature radius of the divided path on the inside (Rib<Roa, Ric<Rob, Rid<Roc, Rie<Rod, Rif<Roe, Rig<Rof, and Rih<Rog). Therefore, a cross-sectional shape of each dividing fin 6 parallel to the curvature radial directions Ria to Rih and Roa to Roh, and the flow direction F of the refrigerant is a crescent shape in which the inside of the bent flow path 3 wanes.

Heights Ha to Hh (FIGS. 5A and 5B) of each of the divided paths 3a to 3h perpendicular to the widths Wa to Wh are constant along the dividing fins 6. Therefore, cross-sectional areas Sa to Sh (FIGS. 5A and 5B) of each of the divided paths 3a to 3h perpendicular to the flow direction F of the refrigerant are also constant along the dividing fins 6.

In addition, the widths Wa to Wh of each of the divided paths 3a to 3h are substantially equal to each other (Wa≅Wb≅Wc≅Wd≅We≅Wf≅Wg≅Wh). The heights Ha to Hh of each of the divided paths 3a to 3h are also substantially equal to each other (Ha≅Hb≅Hc≅Hd≅He≅Hf≅Hg≅Hh). Therefore, the cross-sectional areas Sa to Sh of each of the divided paths 3a to 3h are also substantially equal to each other (Sa≅Sb≅Sc≅Sd≅Se≅Sf≅Sg≅Sh).

Specifically, in the examples of FIGS. 4 and 5A, and 5B, the heights Ha to Hh of each of the divided paths 3a to 3h are equal to each other (Ha=Hb=Hc=Hd=He=Hf=Hg=Hh). Therefore, the widths Wa and Wh, and the cross-sectional areas Sa and Sh of the divided paths 3a and 3h that are in the innermost side and the outermost side of the bent flow path 3 are equal to each other (Wa=Wh and Sa=Sh), and the widths Wb to Wg, and the cross-sectional areas Sb to Sg of the other divided paths 3b to 3g are equal to each other (Wb=Wc=Wd=We=Wf=Wg, and Sb=Sc=Sd=Se=Sf=Sg). The widths Wb to Wg and the cross-sectional areas Sb to Sg of the divided paths 3b to 3g with respect to the widths Wa and Wh, and the cross-sectional areas Sa and Sh of the divided paths 3a and 3h are not equal to each other, but are substantially equal to each other (Wa=Wh≅Wb to Wg, and Sa=Sh≅Sb to Sg).

As described above, the fact that the widths Wa to Wh, the curvature radii Ria to Rih and Roa to Roh, the heights Ha to Hh, and the cross-sectional areas Sa to Sh of each of the divided paths 3a to 3h are constant or substantially equal to each other includes not only a plurality of numerical values to be objects are equal (=) to each other but also a difference between a plurality of numerical values is substantially equal (≅) to or less than a predetermined value. This also applies to the fact that flow speeds of the refrigerant described below are constant or substantially equal to each other.

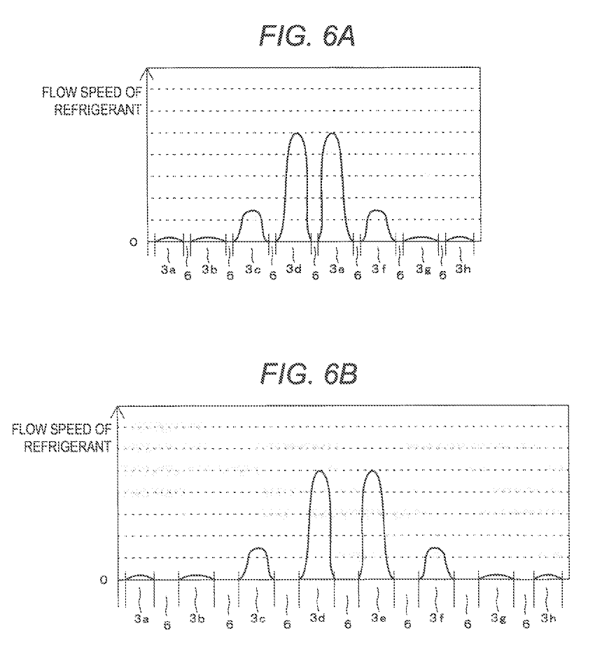

FIGS. 6A and 6B are diagrams illustrating an example of a simulation of the cooler 10. Specifically, as indicated by arrows F in FIG. 1A, in a case where the refrigerant (cooling water) flows in from the narrow flow path 1 of the cooler 10 and the refrigerant flows out from the narrow flow path 5 through the wide flow paths 2 to 4, a flow speed distribution of the cross-sectional area VA-VA of FIG. 4 is illustrated in FIG. 6A and a flow speed distribution of the refrigerant of the refrigerant of the cross-sectional area VB-VB of FIG. 4 is illustrated in FIG. 6B.

As described above, the cross-sectional area of the narrow flow path 1 that is the flow inlet of the refrigerant is narrower than the cross-sectional area of the wide flow paths 2 and 3, and the center lines of the flow paths 1, 2, and 3 coincide (FIG. 1A). Therefore, as illustrated in FIGS. 6A and 613, the flow speed of the refrigerant in the divided paths 3c, 3d, 3e, and 3f that are the center is greater than that in the divided paths 3a, 3b, 3g, and 3h that are the both end sides of the bent flow path 3.

While, the widths Wa to Wh and the cross-sectional areas Sa to Sh of each of the divided paths 3a to 3h are constant along the dividing fins 6. Therefore, the flow speed (FIG. 6A) of the refrigerant flowing through each of the divided paths 3a to 3h of the VA-VA cross-section of FIG. 4 and the flow speed (FIG. 6B) of the refrigerant flowing through each of the divided paths 3a to 3h of the VB-VB cross-section of FIG. 4 are substantially equal to each other. That is, the flow speed of the refrigerant flowing through each of the divided paths 3a to 3h, in the bent flow path 3 is substantially constantly held along the dividing fins 6.

According to the embodiment described above, in the bent flow path 3 and the straight flow paths 2 and 4 of the cooler 10, the widths Wa to Wh of each of the divided paths 3a to 3h divided by the dividing fins 6 are constant along the dividing fins 6. Therefore, it is possible to suppress an decrease in the flow speed of the refrigerant flowing through each of the divided paths 3a to 3h. As a result, the refrigerant smoothly flows through each of the divided paths 3a to 3h, heat generated by the heating body 50 being in thermal contact with the bent flow path 3 can be efficiently radiated by the refrigerant, and the cooling performance is improved.

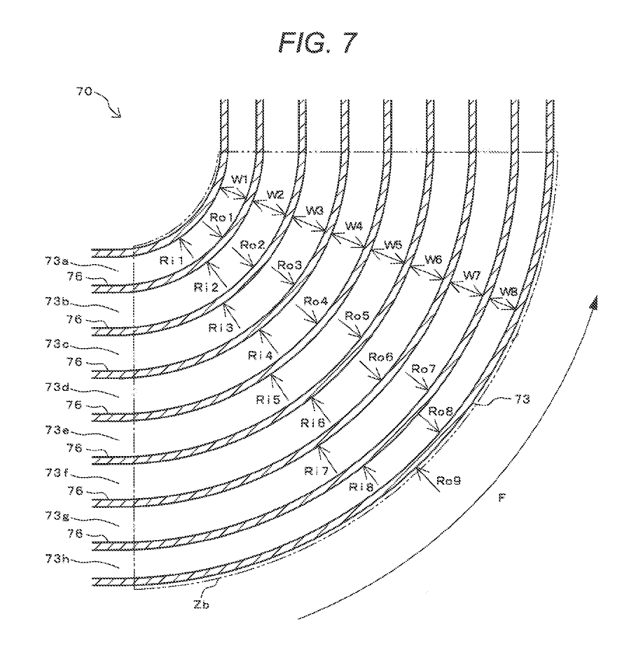

In addition, the inner curvature radii Ria to Rih of each of the divided paths 3a to 3h are substantially equal to each other, the outer curvature radii Roa to Roh are also substantially equal to each other, and the thickness of the curvature radii Ria to Rih and Ron to Roh of the dividing fins 6 in the center portion is thicker than that in the upstream portion or the downstream portion thereof. Therefore, the outer curvature radius Rox (FIG. 4) of the bent flow path 3 can be as small as the outer curvature radius Roa of the divided path 3a that is in the innermost side (Rox≅Ron). Therefore, an entire width Wx (FIG. 5B) of the bent flow path 3 perpendicular to the dividing fins 6 is wider than a sum value of the widths Wa to Wh of each of the divided paths 3a to 3h and thicknesses of both side walls 3k (FIG. 4) of the bent flow path 3. An effective cooling region Za (FIG. 4) capable of being cooled by the refrigerant flowing through the bent flow path 3 can be wider than an effective cooling region Zb of the bent flow path 73 of the related art illustrated in FIG. 7.

As a result, for example, a thermal contact area between the bent flow path 3 and the heating body 50 is increased, heat generated by the heating body 50 can be efficiently radiated by the refrigerant, and the cooling performance is improved.

In addition, the outer curvature radius Rox of the bent flow path 3 can be suppressed as small as the outer curvature radius Roa of the divided path 3a that is in the innermost side. Therefore, it is possible to easily dispose the bent flow path 3 along a narrow portion such as the corner portion 41 (FIG. 3) of the housing 40. Therefore, heat generated by the heating body 50 mounted on the narrow portion is efficiently radiated by the refrigerant flowing through the bent flow path 3 and it is possible to improve the cooling performance. In addition, a dead space of the housing 40 which cannot be cooled by the bent flow path 3 is reduced and the effective cooling region Za of the bent flow path 3 is widened. Therefore, it is possible to easily dispose the heating body 50 or other components on the housing 40. That is, it is possible to increase a degree of freedom in disposition of the heating body 50 or other components on the housing 40.

In addition, in the embodiments described above, the cross-sectional areas Sa to Sh of each of the divided paths 3a to 3h perpendicular to the flow direction F of the refrigerant are constant along the dividing fins 6. Therefore, a decrease in the flow speed of the refrigerant flowing through each of the divided paths 3a to 3h can be further suppressed in the corner portion.

In addition, in the embodiments described above, as illustrated in FIG. 4, the cross-sectional shape of the dividing fins 6 parallel to the curvature radial directions Ria to Rih and Roa to Roh of the bent flow path 3, and the flow direction F of the refrigerant is the crescent shape. Therefore, it is possible to reliably realize that the inner curvature radii Ria to Rih of each of the divided paths 3a to 3h are substantially equal to each other, and the outer curvature radii Roa to Rob are substantially equal to each other while the widths Wa to Wh of each of the divided paths 3a to 3h are constant along the dividing fins 6. In addition, since the dividing fins 6 are formed of metal having high thermal conductivity, the portion of the crescent shape in cross-sectional of the dividing fins 6 efficiently transmits heat from the heating body to the refrigerant and can cool the heating body.

In addition, in the embodiments described above, since the widths Wa to Wh of each of the divided paths 3a to 3h are substantially equal to each other, the cross-sectional areas Sa to Sh of each of the divided paths 3a to 3h are also substantially equal to each other. Therefore, a difference in a flow rate and the flow speed of the refrigerant flowing through each of the divided paths 3a to 3h can be suppressed small. In addition, it is possible to avoid the shape of the dividing fin 6 becoming complicated.

In addition, in the embodiments described above, the dividing fins 6 are provided parallel to the flow direction F of the refrigerant and over the upstream-side straight flow path 2, the bent flow path 3, and the downstream-side straight flow path 4. Therefore, the divided paths 3a to 3h are formed over the flow paths 2 to 4, and the widths Wa to Wh, the cross-sectional areas Sa to Sh of the divided paths 3a to 3h, and the flow speed of the refrigerant can be constant over the flow paths 2 to 4.

Furthermore, in the embodiments described above, the cross-sectional shape of the bent flow path 3 is rectangular and the dividing fins 6 are provided in the columnar shape in the bent flow path 3. Therefore, the cross-sectional shape of each of the divided paths 3a to 3h perpendicular to the flow direction F of the refrigerant is also rectangular and it is possible to easily form the dividing fins 6. In addition, a difference in the flow rate and the flow speed of the refrigerant flowing through each of the divided paths 3a to 3h can be suppressed small. Furthermore, since the dividing fins 6 function as radiating fins, heat generated by the heating body 50 is easily transmitted to the refrigerant flowing through each of the divided paths 3a to 3h through the dividing fins 6 and it is possible to further improve the cooling performance.

One or more embodiments of the invention can adopt various embodiments other than the above embodiments. For example, in the embodiments described above, as illustrated in FIG. 4, or the like, an example, in which the dividing fins 6 are provided in the bent flow path 3 that is bent to substantially 90°, is illustrated, but one or more embodiments of the invention are not limited only to the example. In addition, one or two or more dividing fins is provided in a bent flow path that is bent to an angle (acute angle or obtuse angle) other than 90° and the bent flow path may be divided into two or more.

In addition, in the embodiments described above, an example, in which the dividing fins 6 are provided over the upstream-side straight flow path 2, the bent flow path 3, and the downstream-side straight flow path 4, is illustrated, but one or more embodiments of the invention are not limited only to the example. In addition, the dividing fins are provided only in the bent flow path, or the dividing fins may be provided in the bent flow path and the straight flow path continuous to one of the upstream side and the downstream side thereof.

In addition, in the embodiments described above, an example, in which the dividing fins 6 are provided in the columnar shape in the bent flow path 3 or the like, is illustrated, but one or more embodiments of the invention are not limited only to the example. In addition, for example, boss-shaped dividing fins may be provided so as to connect to only the bottom surface of the bent flow path.

In addition, in the embodiments described above, an example, in which the cross-sectional shape of the bent flow path 3 is rectangular, is illustrated, but one or more embodiments of the invention are not limited only to the example. In addition, for example, the cross-sectional shape of the bent flow path may be a circular shape, an elliptical shape, or another shape.

Furthermore, in the embodiments described above, an example, in which one or more embodiments of the invention are applied to the cooler 10 that is disposed within the housing 40 of the electronic device and cools the heating body 50 mounted on the housing 40, is illustrated, but for example, one or more embodiments of the invention can also be applied to a cooler that is mounted on a frame or a chassis and cools the heating body mounted on a substrate or the like. Furthermore, one or more embodiments of the invention can be applied to a flow path unit including a bent flow path which is used for applications other than cooling.

While the invention has been described with respect to a limited number of embodiments, those skilled in the art, having benefit of this disclosure, will appreciate that other embodiments can be devised which do not depart from the scope of the invention as disclosed herein. According, the scope of the invention should be limited only by the attached claims.

1. A cooler comprising:
a bent flow path that is in thermal contact with a heating body, bends a flow direction of a refrigerant flowing in from an upstream, and causes the refrigerant to flow out to a downstream; and
a dividing fin that divides the bent flow path into two or more divided paths in a curvature radial direction,
wherein the refrigerant flows through each of the divided paths of the bent flow path, and heat generated by the heating body is radiated,
wherein a width of each of the divided paths in the curvature radial direction of the bent flow path is constant along the dividing fin,
wherein inner curvature radii of the divided paths are substantially equal to each other, and outer curvature radii of the divided paths are substantially equal to each other, and
wherein a thickness of the dividing fin in a center portion of the bent flow path in the curvature radial direction is thicker than a thickness of the dividing fin in an upstream portion and a downstream portion of the bent flow path in the curvature radial direction.

2. The cooler according to claim 1,
wherein a cross-sectional area of each of the divided paths perpendicular to the flow direction of the refrigerant is constant along the dividing fin.

3. The cooler according to claim 3,
wherein a cross-sectional shape of the dividing fin parallel to the curvature radial direction of the bent flow path and the flow direction of the refrigerant is a crescent shape in which an inside of the bent flow path wanes.

4. The cooler according to claim 1,
wherein widths of the divided paths perpendicular to the dividing fin are substantially equal to each other, or the cross-sectional areas of the divided paths perpendicular to the flow direction of the refrigerant are substantially equal to each other.

5. The cooler according to claim 1, further comprising:
an upstream-side straight flow path that is connected to an upstream side of the bent flow path and causes the refrigerant to straightly flow; and
a downstream-side straight flow path that is connected to a downstream side of the bent flow path and causes the refrigerant to straightly flow,
wherein the dividing fin is provided in parallel to the flow direction of the refrigerant and over the upstream-side straight flow path, the bent flow path, and the downstream-side straight flow path.

6. The cooler according to claim 1,
wherein a cross-sectional shape of the bent flow path perpendicular to the flow direction of the refrigerant is rectangular, and
wherein the dividing fin is provided to have a columnar shape in the bent flow path and transmits heat generated by the heating body to the refrigerant.

7. A flow path unit comprising:
a bent flow path that bends a flow direction of a fluid flowing in from an upstream and causes the fluid to flow out to a downstream; and
a dividing fin that divides the bent flow path into two or more divided paths in a curvature radial direction,
wherein the fluid flows through each of the divided paths of the bent flow path,
wherein a width of each of the divided paths in the curvature radial direction of the bent flow path is constant along the dividing fin,
wherein inner curvature radii of the divided paths are substantially equal to each other, and outer curvature radii of the divided paths are substantially equal to each other, and
wherein a thickness of the dividing fin in a center portion of the bent flow path in the curvature radial direction is thicker than a thickness of the dividing fin in an upstream portion and a downstream portion of the bent flow path in the curvature radial direction.
